(19) United States
(12) Patent Application Publication
(10) Pub. No.: US 2014/0053895 A1
(43) Pub. Date: Feb. 27, 2014

(54) INTENTIONALLY-DOPED CADMIUM OXIDE LAYER FOR SOLAR CELLS

(71) Applicant: ROSESTREET LABS, LLC, Phoenix, AZ (US)

(72) Inventors: LOTHAR A. REICHERTZ, Berkeley, CA (US); Robert Forcier, Mesa, AZ (US)

(73) Assignee: RoseStreet Labs, LLC, Phoenix, AZ (US)

(21) Appl. No.: 13/793,930

(22) Filed: Mar. 11, 2013

Related U.S. Application Data
(60) Provisional application No. 61/692,773, filed on Aug. 24, 2012.
(60) Provisional application No. 61/753,516, filed on Jan. 17, 2013.

(51) Int. Cl. H01L 31/0296; H01L 31/0216

(52) U.S. Cl. CPC H01L 31/02963; H01L 31/02168; H01L 31/02966
USPC 136/255; 136/256; 438/72

(57) ABSTRACT

A method and structure for a solar cell forms and utilizes a low resistivity and high transmission semiconductor in a top and/or bottom layer (e.g., a top or bottom contact). Some embodiments relate to solar cells having a top or bottom transparent contact layer comprising doped cadmium oxide (CdO) or alloys of CdO.

### CROSS-REFERENCE TO RELATED APPLICATIONS

The present application claims priority to U.S. Provisional Application Ser. No. 61/692,773, filed Aug. 24, 2012, entitled “METHOD TO INCREASE PERFORMANCE AND REDUCE COST IN SOLAR CELL TECHNOLOGY BY USING A SPUTTERED, HIGHLY CONDUCTING AND TRANSPARENT CADMIUM OXIDE EMITTER,” by Reichertz et al., and also claims priority to U.S. Provisional Application Ser. No. 61/753,516, filed Jan. 17, 2013, entitled “METHOD TO UTILIZE A LAYER OF CADMIUM OXIDE AS TRANSPARENT CONTACT, ANTI-REFLECTIVE COATING, AND SURFACE PASSIVATION IN SOLAR CELL TECHNOLOGIES,” by Reichertz et al., the entire contents of which applications are incorporated by reference as if fully set forth herein.

### FIELD OF THE TECHNOLOGY

The present disclosure generally relates to structures and methods for forming solar cells, and more particularly to structures and methods for forming solar cells using cadmium oxide in a top or bottom contact layer of a solar cell.

### BACKGROUND

A typical solar cell has a top and bottom contact (e.g., an electrode) to facilitate an electrical connection. The top contact should be transparent to the extent possible because the top side of the solar cell is exposed to the light that is being converted to electrical power inside the cell.

There are at least two approaches currently being utilized to form the top contact of sufficient transparency for solar cells. In one approach, the top contact is made of a metal grid, consisting of a series of narrow metal strips, called fingers, with spacing in between such that overall, only a small percentage of the solar cell's top surface is covered with metal. See, e.g., A. R. Burgers, How to Design Optimal Metallization Patterns for Solar Cells, Prog. Photovolt: Res. Appl. 7, 457-461 (1999), incorporated herein by reference in its entirety. In another approach, the top contact can be made from a continuous layer of a transparent conductor, usually a transparent conducting oxide (TCO).

The preferred approach in forming the top transparent contact is governed by various conditions and optimizations surrounding the particular use of the solar cell. Metal grids are being used in standard silicon photovoltaics (PV) technology and in III-V compound semiconductor high efficiency solar cells. TCOs are being used in thin film PV technologies like cadmium telluride (CdTe) or copper indium gallium selenide (CIGS). The uniform coating with TCOs allows for a better lateral current spreading. The use of a metal grid requires a lower sheet resistivity in the upper layer of the solar cell (emitter layer).

Currently, the highest efficiency solar cells are triple junction solar cells. These solar cells use optical concentrators to further increase efficiency and to reduce the amount of cell material needed for a given area of the solar panel. A typical concentration factor is 500× leading to current densities (J) of up to approximately 7 A/cm² in the solar cell. In order to minimize losses due to such high current densities, the series resistance of the cell has to be minimized.

In light of the need to minimize the series resistance, a metal grid is typically utilized as the resistivity of TCOs is at least an order of magnitude higher than metals (e.g., a metal such as silver). Furthermore, commonly used TCOs like indium tin oxide (ITO) or aluminum zinc oxide (AZO) are highly n-type doped semiconductors. As such, they have significant free carrier absorption at near infrared wavelengths. This significant carrier absorption is yet another disadvantage of using TCOs as the transparent contact, and disallows their usage in triple junction solar cells that have an extended long wavelength of up to 1700 nm. TCOs do not even play a role in standard silicon PV technology with low current densities because of the near infrared absorption.

### SUMMARY OF THE DESCRIPTION

Various embodiments disclosed herein relate to a method and structure for increasing performance in solar cells by forming and utilizing a low resistivity and high transmission semiconductor in a top and/or bottom transparent contact layer. Some embodiments are summarized in this section.

In one embodiment, an apparatus includes a solar cell structure (e.g., for a multi-junction solar cell), and an intentionally-doped cadmium oxide layer overlying the solar cell structure.

In another embodiment, a solar cell includes a semiconductor wafer (e.g., a silicon wafer), and a top cadmium oxide layer overlying the wafer, wherein the cadmium oxide layer is doped with an n-type dopant.

In another embodiment, a solar cell includes a thin film solar cell (e.g., based on CdTe, CIGS, or CZTS, etc.), and a top cadmium oxide layer overlying an emitter layer of the solar cell. The cadmium oxide layer is doped with an n-type dopant such as, for example, indium or gallium.

In another embodiment, a method includes forming a solar cell structure, and forming a cadmium oxide layer underlying or overlying the solar cell structure (e.g., a top CdO layer that functions as both a contact layer and an anti-reflective coating). In one embodiment, the cadmium oxide layer is formed by sputtering.

Other features will be apparent from the accompanying drawings and from the detailed description which follows.

### BRIEF DESCRIPTION OF THE DRAWINGS

The embodiments are illustrated by way of example and not limitation in the figures of the accompanying drawings in which like references indicate similar elements.

FIG. 1 shows a transmission spectrum of an RF magnetron sputtered CdO film on a glass substrate as compared to the AM1.5G solar spectrum.

FIG. 2 shows a computer simulation of the electrical potential near the metal grid fingers of a typical high efficiency solar cell under 500× concentrated solar illumination. The grey scale in this image ranges from 0.0 V (dark) to 0.105 V (light).

FIG. 3 shows a computer simulation of the electrical potential near metal grid fingers under the same conditions as in FIG. 2, but with an additional layer of CdO, according to one embodiment. The grey scale in this image ranges from 0.0 V (dark) to 0.0148 V (light).

FIG. 4 shows an example of a solar cell structure with an additional CdO layer, according to one embodiment.

FIG. 5 shows a calculated band diagram of the interface between CdO and the n-type emitter of a p-type silicon wafer-based solar cell. The band bending on the silicon (Si) side leads to an unwanted increased resistance for the charge carriers, in this case electrons, which flow from Si to CdO.

FIG. 6 shows a calculated band diagram of the interface between CdO and the p-type emitter of an n-type silicon wafer-based solar cell. The valence band of the silicon (Si) side is well-connected to the conduction band of CdO, resulting in a low resistance for the charge carriers, in this case holes, which flow from Si to CdO, according to one embodiment.

FIG. 7 shows an example of a standard silicon solar cell structure with the CdO layer. The CdO layer functions as a passivation layer, ARC layer and contact layer, according to one embodiment.

FIG. 8 shows an example of an HIT silicon solar cell structure with CdO layers on the front side and on the back side, according to one embodiment. The front-side CdO layer functions as an ARC layer and as a contact layer. The back-side CdO layer reduces light reflection losses at the back contact.

### DETAILED DESCRIPTION

The following description and drawings are illustrative and are not to be construed as limiting. Numerous specific details are described to provide a thorough understanding. However, in certain instances, well known or conventional details are not described in order to avoid obscuring the description. References to one or an embodiment in the present disclosure are not necessarily references to the same embodiment; and, such references mean at least one.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

As used herein, “cadmium oxide layer” means a layer including cadmium oxide and/or alloys of cadmium oxide (e.g., CdZnO).

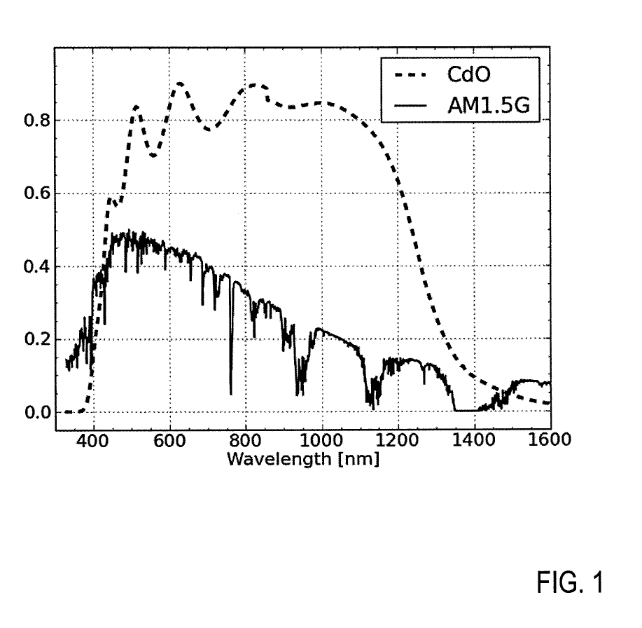

As illustrated in FIG. 1, according to one embodiment, the semiconductor cadmium oxide (CdO), if doped in a particular way, can have a very low resistivity and high transmission, even at near infrared wavelengths. Un-doped CdO has a band gap of 2.16 eV. Therefore, un-doped CdO has the disadvantage of absorbing light of wavelengths shorter than approximately 574 nm.

Due to its large electron affinity, CdO as deposited is already heavily n-type doped by native defects in the material (with a typical electron concentration of around 10²⁰ cm⁻³). This already shifts the absorption edge to shorter wavelengths, but it still remains in the visible range of the spectrum. This has restricted the use of CdO as a transparent conductor in the past.

By intentionally adding n-type dopants (e.g., such as indium or gallium) during the deposition process or otherwise, the doping level can be increased even further (e.g., into an electron concentration range equal to or greater than 10²¹ cm⁻³). With this intentional doping, the absorption edge shifts to less than approximately 400 nm (due to the Burstein-Moss shift effect).

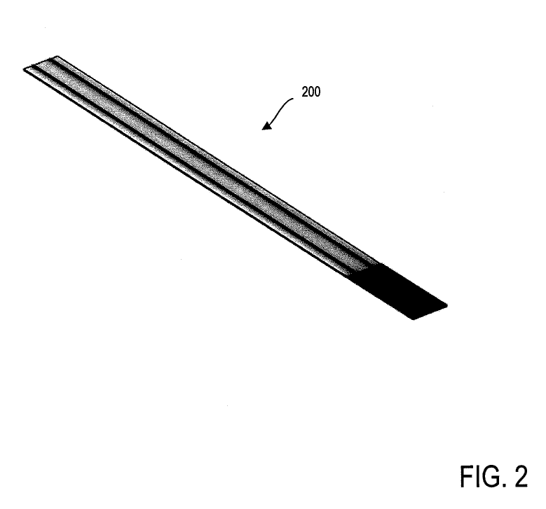

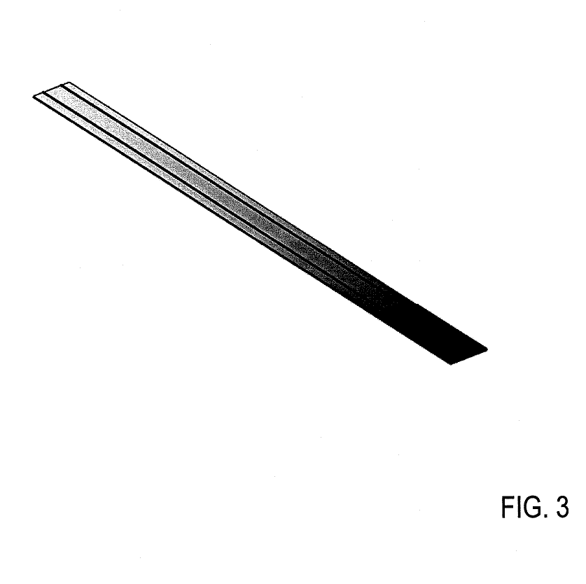

In contrast to most other semiconductors, the electron mobility in CdO is not reduced at these very high doping levels. Indeed, the mobility is significantly higher than in other TCOs, and as a result, the free carrier absorption remains low in the near-infrared region. This characteristic makes it possible to use a CdO layer in solar cells to improve their performance or to reduce cost. In applications which desire an absorption edge at even lower wavelengths, CdO can be alloyed with an oxide of larger bandgap, for instance ZnO, which would result in CdZnO. The composition of such a ternary semiconductor can be adjusted for the required absorption edge. Consistent with the foregoing, some embodiments disclosed herein are solar cells which include CdO in the upper-most layer to reduce the sheet resistivity of this layer, and thereby improve the current flow between the fingers of the metal grid (as further illustrated in FIGS. 2 and 3 discussed below).

FIG. 2 illustrates the result of a finite element (FEM) computer simulation for a typical multi-junction solar cell with a power conversion efficiency of 40% under 500× concentrated solar irradiation, thus having a current density of J=6.7 A/cm². A typical solar cell for this application has a regular metal grid with 5 micron wide fingers on a 100 micron pitch. The simulated solar cell included a metal grid with fingers having a 1.6×10⁻⁶ ohm-cm finger resistivity and an emitter sheet having a resistivity of 100 ohm/sq.

The plot 200 in FIG. 2 illustrates a section of the top of the cell with the resulting potential distribution around the fingers expressed in grey-scale. It can be seen that most of the voltage drop occurs between the fingers due to the resistivity of the emitter. The maximum voltage drop between emitter and electrical contact in this example is 0.105 V.

FIG. 3 illustrates performance improvements of an exemplary embodiment over the multi-junction solar cell tested in FIG. 2. In the exemplary embodiment, an additional CdO layer of 0.3 micron thickness and 3×10⁻⁵ ohm-cm resistivity was deposited onto the emitter beneath the metal grid. As illustrated in FIG. 3, the addition of the CdO layer causes significant changes in the potential distribution, minimizing the voltage drop between the fingers to a maximum voltage drop of approximately 0.0148 V. This minimized voltage drop corresponds to a seven-fold reduced series resistance over the case without the CdO layer.

Various embodiments disclosed herein are utilized in concentrated PV applications. Other embodiments can be utilized in standard un-concentrated applications. The reduction of the series resistance in the solar cell translates to an increased fill factor and therefore higher efficiency. It will also allow reducing the density of the fingers and therefore increase the efficiency through reduced shading losses. In particular cases the metal grid can be partially or entirely replaced by the CdO. This is a cost advantage since, for example, in silicon PV technology, the silver metal used to form the grid has become a major cost factor. A reduced series resistance will also allow for higher concentration factors in PV, which is a direct cost and efficiency advantage.

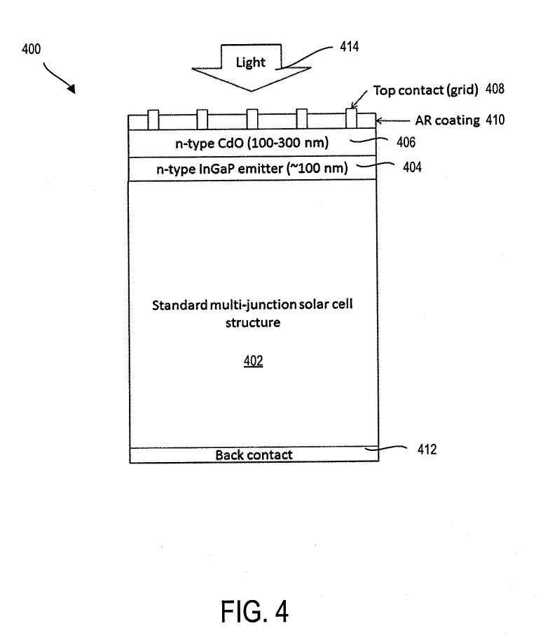

FIG. 4 illustrates an embodiment as a multi-junction solar cell 400 having a top layer comprising a metal grid having one or more fingers and an emitter layer. A TCO layer comprises a CdO layer 406 connected in between the fingers of a metal grid 408 on one side, and connected to an InGaP emitter layer 404 on the other side.

Metal grid 408 provides a top contact. Anti-reflective coating 410 is disposed on CdO layer 406. A back contact 412 is disposed underlying a standard multi-junction solar cell structure 402 (e.g., formed using III-V semiconductors). Light 414 impinges a top surface of solar cell 400.

In one example, the CdO layer 406 is an n-type CdO layer having a thickness in the range of approximately 100 to 300 nm. The thickness can be adjusted for optimum anti-reflective properties of the CdO layer. In one example, the InGaP emitter layer 404 is an n-type InGaP layer having a thickness of approximately 100 nm.

Other embodiments (not shown in FIG. 4) are solar cells having a top layer comprising an emitter layer, wherein the emitter layer comprises a CdO layer. In one embodiment, the CdO layer has a thickness in the range of approximately 50 to 300 nm, and even more specifically 100 to 300 nm. In one embodiment, the emitter layer further comprises an InGaP layer connected to the CdO layer, wherein the InGaP layer is an n-type InGaP layer having a thickness of approximately 100 nm.

In PV technologies, an anti-reflective coating (ARC) is usually used to help improve the solar cell's efficiency by minimizing the cell's reflection losses. To optimally minimize such reflection losses, the ARC preferably has an optimum refractive index and an optimum thickness. In silicon PV technology, for example, trisilicon tetranitride (Si₃N₄) is commonly used to minimize reflection losses. CdO has a refractive index similar to that of Si₃N₄. Therefore, CdO can simultaneously serve a current collection function as well as an anti-reflective coating function, thereby making an additional ARC layer (e.g., a Si₃N₄ layer) unnecessary. In other words, the CdO layer as described herein can be used as the ARC, and no further ARC layer is required in the solar cell.

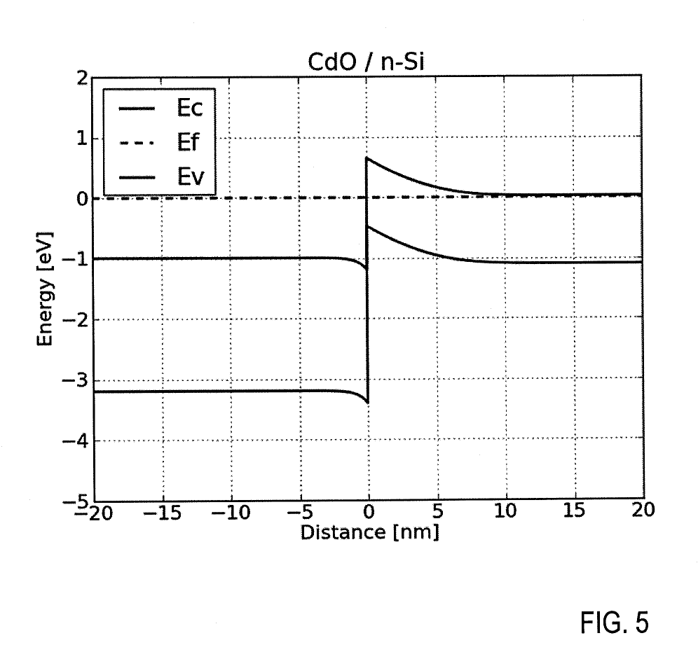

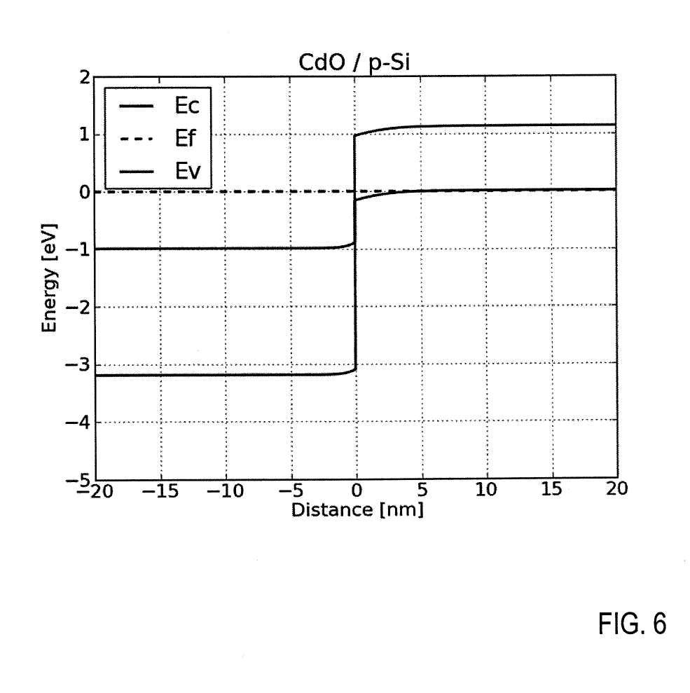

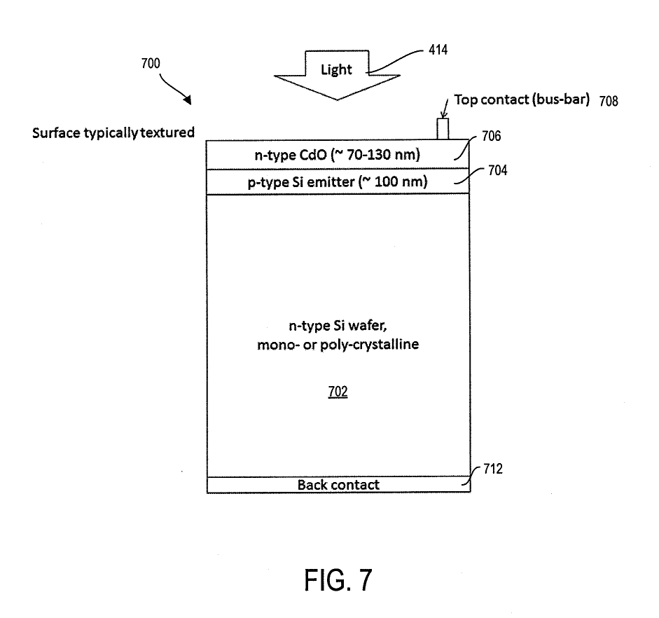

As illustrated in FIG. 5, CdO can be used in standard silicon PV technology based on p-type wafers with n-type emitter layers. However, as illustrated by FIGS. 5 and 6, the band alignment between CdO and silicon is more favorable for n-type Si wafer-based technology in which CdO comes in direct contact with a p-type emitter, as further illustrated in the exemplary embodiment of FIG. 7 (discussed in detail below).

The calculated band diagrams illustrated in FIGS. 5 and 6 compare the two above scenarios. As illustrated in FIG. 5, when CdO is used with a p-type wafer and an n-type emitter layer, a barrier for electrons is formed. This barrier increases the contact resistance between silicon and CdO, which may require an additional layer between the silicon and CdO in order to alleviate the increased resistance.

In contrast, as illustrated in the band diagram of FIG. 6, when CdO is used with a p-type emitter of an n-type Si wafer-based solar cell, there is very little barrier for the charge carriers (in this case holes) to reach the CdO contact layer. This configuration, such as the example specifically illustrated in FIG. 7, has yet another advantage: n-type CdO acts as a passivation layer on p-type silicon. The passivation effect can be maximized by choosing a lower doping level at the interface to silicon and subsequently grading the layer to a higher doping level for highest conductivity and transmission. In light of the foregoing, therefore, when CdO is interfaced with the p-type emitter of an n-type Si wafer-based solar cell, as exemplary illustrated in FIG. 7, the CdO layer simultaneously serves as a transparent contact layer, an anti-reflective coating, and a passivation layer on p-type silicon.

In more detail, FIG. 7 illustrates a solar cell 700 having an n-type silicon wafer 702 (e.g., mono or poly-crystalline). A back contact layer 712 underlies wafer 702. A p-type silicon emitter layer 704 (e.g., of thickness 100 nm) is on wafer 702. CdO layer 706 is on emitter layer 704. CdO layer 706 in this embodiment is n-type and has a thickness, for example, of 70-130 nm. A top contact 708 (e.g., a bus bar) is on CdO layer 706.

The top surface of silicon wafer 702 is usually textured (to reduce reflection losses), in which case the CdO layer 706 resembles this texture (this texturing is not shown in this drawing for simplification of illustration).

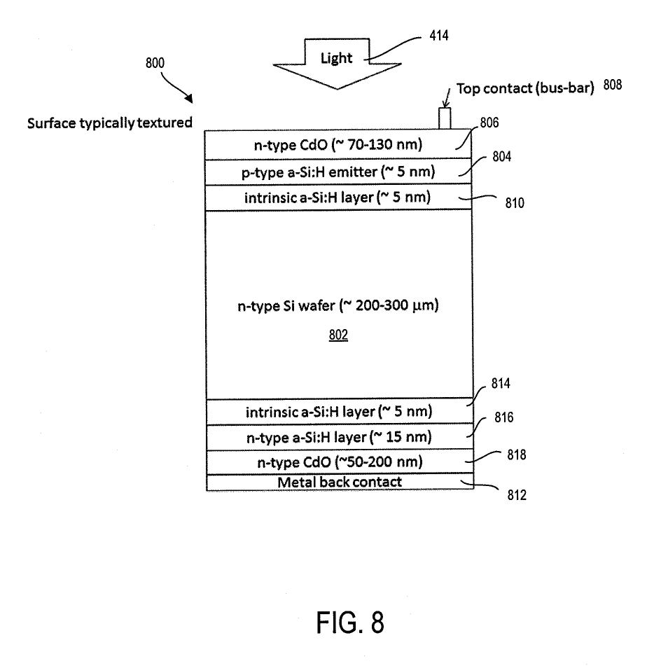

Another possible application for CdO is in hetero-junction with intrinsic thin-layer (HIT) cell technology, as for example illustrated in FIG. 8 discussed below. HIT cells are based on a heterojunction between a thin amorphous silicon layer and a crystalline silicon wafer. The amorphous silicon layer on the surface of the cell has excellent passivation properties, but a relatively high electrical resistance. Therefore, HIT cells use an additional TCO layer between the metal grid fingers. This TCO layer is usually made of indium tin oxide (ITO).

However, using ITO as the TCO layer has disadvantages. For example, the indium component in ITO is expensive. Also, ITO has to be low-doped to avoid absorption at infrared wavelengths, which limits ITO's lateral conductivity. Further, the thickness of the top layer is generally limited in light of the anti-reflective function required of the top layer.

As illustrated in the exemplary embodiment of FIG. 8, for example, CdO can be used in HIT cell technology. In further detail, FIG. 8 illustrates a solar cell 800 having an n-type silicon wafer 802 (e.g., of thickness 200-300 microns). Intrinsic hydrogenated amorphous silicon layer 810 is on wafer 802. A p-type hydrogenated amorphous silicon emitter layer 804 is on layer 810. CdO layer 806 is on layer 804. Top contact 808 is on CdO layer 806.

Intrinsic hydrogenated amorphous silicon layer 814 is on a bottom side of silicon wafer 802, and n-type hydrogenated amorphous silicon layer 816 underlies layer 814. CdO layer 818 is a back contact layer formed on layer 816. A back contact 812 is formed on CdO layer 818.

With less infrared absorption and significantly higher conductivity, utilizing CdO in an HIT cell permits reduction of the cell's metal grid fingers, which in turn allows reduction of the amount of shading losses. Further, a top CdO layer can be made optimally thin for anti-reflective purposes.

In some embodiments, the TCO layer comprises n-type CdO layer 806 having a thickness of approximately 70 to 130 nm, connected between top contact 808 (e.g., a bus-bar) on one side, and connected to p-type hydrogenated amorphous silicon (a-Si:H) layer 804 on the other side (e.g., layer 804 has a thickness of approximately 5 nm). As further illustrated in FIG. 8, in one example, p-type a-Si:H layer 804 is also connected to intrinsic a-Si:H layer 810, which is approximately 5 nm in thickness.

The improved infrared transmission characteristics also make CdO suitable for the back contact side in HIT cells (and also in other types of solar cells). As illustrated in FIG. 8, in one embodiment, a TCO layer between the silicon wafer 802 and the metal back contact 812 is utilized to improve the back-reflection of the infrared light. In some examples, the TCO layer connected between the silicon wafer 802 and the metal back contact 812 comprises n-type CdO layer 818 (formed of CdO or one of its alloys) of approximately 50 to 200 nm in thickness, connected between metal back contact 812 and n-type a-Si:H layer 816 of approximately 15 nm in thickness. As further illustrated in FIG. 8, in one example, n-type a-Si:H layer 816 is also connected to intrinsic a-Si:H layer 814 of approximately 5 nm in thickness.

The top surface of CdO layer 806 may have a texture that resembles the underlying texture of silicon wafer 802, as was discussed above for CdO layer 706 of FIG. 7.

In alternative embodiments of FIG. 4, 7, or 8, the bottom cadmium oxide layer may be used without the top cadmium oxide layer. For example, this may be done when it is merely desired to reduce light reflection losses at the back contact. Possible applications of the foregoing include, for example, inverted metamorphic multi-junction solar cells and solar cells made with epitaxial lift-off technology (e.g., used by Alta Devices).

In other various embodiments, the cadmium oxide layer (CdO or related alloys) as described above is not restricted to use with a particular solar cell material. In addition to silicon technologies and III-V technologies, it also can be used in CdTe, CIGS, CZTS, thin-film silicon, and organic PV technologies, as a front and as well as a back contact layer with the previously-described advantages. Possible applications also include photovoltaic cells in mobile devices, smart phones, tablets and other electronic devices (e.g., achieved by integrating PV into these devices).

Various embodiments are further described below. In a first embodiment, an apparatus includes a solar cell structure, and a cadmium oxide layer overlying the solar cell structure. In one embodiment, the apparatus further comprises an anti-reflective coating overlying the cadmium oxide layer, and a back contact underlying the solar cell structure. In one embodiment, the cadmium oxide layer has a thickness of 50 to 300 nm, or even more specifically 100 to 300 nm.

In one embodiment, the apparatus further comprises an emitter layer (part of the solar cell structure) underlying the cadmium oxide layer. In one embodiment, the emitter layer is an n-type InGaP layer, a p-type silicon layer, an n-type silicon layer, an amorphous silicon layer (n-type or p-type), or a cadmium sulfide layer (e.g., an n-type CdS layer). The cadmium sulfide layer is usually based on CdTe and CIGS technology.

In one embodiment, the solar cell structure is a multi-junction solar cell structure, or is based on an n-type silicon wafer. In one embodiment, the solar cell structure is based on an n-type silicon wafer, and the apparatus further comprises a p-type silicon emitter layer between the cadmium oxide layer and the silicon wafer.

It should be noted that in alternative embodiments, the solar cell structure may be based on p-type silicon wafers. In yet other embodiments, the solar cell structure may be based on any thin-film solar cell structure like CdTe, CIGS, CZTS or thin-film silicon. In other embodiments, the solar cell structure may be based on either a monocrystalline or polycrystalline silicon wafer (e.g., for the silicon wafer as illustrated in FIG. 7 or 8).

In one embodiment, the cadmium oxide layer is a top contact layer and functions as an anti-reflective coating. In one embodiment, the cadmium oxide layer further functions as a passivation layer. In one embodiment, the apparatus further comprises a top contact grid overlying the cadmium oxide layer.

In other embodiments, the apparatus further comprises a metal contact on a back side of the solar cell structure, wherein the cadmium oxide layer is located between the solar cell structure and the metal contact in order to improve back-side reflectivity. The solar cell structure may be a silicon solar cell, a thin film solar cell, a multi-junction solar cell, an inverted metamorphic multi-junction solar cell, or an epitaxial lift-off solar cell.

In another embodiment, a solar cell includes a semiconductor wafer, and a top cadmium oxide layer overlying the wafer. In one embodiment, the solar cell further comprises a bottom cadmium oxide layer underlying the semiconductor wafer. In one embodiment, the semiconductor wafer is a crystalline silicon wafer, and the solar cell further comprises a p-type amorphous silicon layer overlying the crystalline silicon wafer.

In one embodiment, the p-type amorphous silicon layer is an emitter underlying the top cadmium oxide layer, and the top cadmium oxide layer is n-type. In one embodiment, the bottom cadmium oxide layer is n-type, and the solar cell further comprises an n-type amorphous silicon layer underlying the semiconductor wafer and overlying the bottom cadmium oxide layer.

In one embodiment, the top cadmium oxide layer has a thickness of 70 to 130 nm, and the bottom cadmium oxide layer has a thickness of 50 to 200 nm. In one embodiment, the semiconductor wafer comprises a multi-junction solar cell structure, and the solar cell further comprises an emitter layer (as part of the multi-junction solar cell structure) underlying the top cadmium oxide layer.

In another embodiment, a method includes forming a solar cell structure, and forming a cadmium oxide layer underlying or overlying the solar cell structure.

In one embodiment, the cadmium oxide layer is formed using CdO that has been doped with an n-type dopant such as, for example, indium or gallium.

In one embodiment, CdO in the cadmium oxide layer has been alloyed with ZnO, MgO or other metal-oxides in order to adjust the transmission spectrum of the cadmium oxide layer.

In one embodiment, the cadmium oxide layer is formed by sputtering. In one embodiment, the cadmium oxide layer is formed to have a thickness of 100 to 300 nm. In another embodiment the cadmium oxide layer is first formed on a superstrate (e.g., glass), then a thin-film solar cell structure (e.g., CdTe technology) is formed, overlying the cadmium oxide in a top-to-bottom process (superstrate configuration).

Additional information regarding resistivity or transmission characteristics of cadmium oxide (CdO), and/or CdO's energy band structure, can be found, for example, in K. M. Yu et al., Ideal Transparent Conductors For Full Spectrum Photovoltaics, Journal of Applied Physics 111, 123505 (2012), and P. H. Jefferson et al., Bandgap and Effective Mass of Epitaxial Cadmium Oxide, Applied Physics Letters, 92(2): 022101 (2008), each of which is incorporated herein by reference in its entirety.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

What is claimed is:

1. An apparatus, comprising:
a solar cell structure; and
a doped cadmium oxide layer overlying the solar cell structure.

2. The apparatus of claim 1, further comprising a metal contact on a back side of the solar cell structure, wherein an additional cadmium oxide layer is located between the solar cell structure and the metal contact in order to improve back-side reflectivity.

3. The apparatus of claim 2, wherein the solar cell structure is a silicon solar cell, a thin film solar cell, a multi-junction solar cell, an inverted metamorphic multi-junction solar cell, or an epitaxial lift-off solar cell.

4. The apparatus of claim 1, further comprising an anti-reflective coating overlying the cadmium oxide layer, and a back contact underlying the solar cell structure.

5. The apparatus of claim 1, wherein the cadmium oxide layer has a thickness of 50 to 300 nm.

6. The apparatus of claim 1, wherein the solar cell structure includes an emitter layer, and the cadmium oxide layer overlies the emitter layer.

7. The apparatus of claim 6, wherein the emitter layer is an n-type InGaP layer, a p-type silicon layer, an n-type silicon layer, a p-type amorphous silicon layer, an n-type amorphous silicon layer, or an n-type cadmium sulfide layer.

8. The apparatus of claim 1, wherein the solar cell structure is a structure selected from the group consisting of:
a multi-junction solar cell structure;
a structure based on an n-type silicon wafer;
a structure based on a p-type silicon wafer;
a structure based on a monocrystalline or polycrystalline silicon wafer; and
a thin-film solar cell structure using CdTe, CIGS, CZTS, or thin-film silicon.

9. The apparatus of claim 1, wherein the solar cell structure is based on an n-type silicon wafer, and further comprising a p-type silicon emitter layer between the cadmium oxide layer and the silicon wafer.

10. The apparatus of claim 1, wherein the cadmium oxide layer is a top contact layer and functions as an anti-reflective coating.

11. The apparatus of claim 10, wherein the cadmium oxide layer further functions as a passivation layer.

12. The apparatus of claim 1, further comprising a top contact grid overlying the cadmium oxide layer.

13. A solar cell, comprising:
a semiconductor wafer; and
a top cadmium oxide layer overlying the wafer, wherein the cadmium oxide layer is doped with an n-type dopant.

14. The solar cell of claim 13, wherein the n-type dopant is indium or gallium.

15. The solar cell of claim 13, further comprising a bottom cadmium oxide layer underlying the semiconductor wafer.

16. The solar cell of claim 13, wherein the semiconductor wafer is a crystalline silicon wafer, and further comprising a p-type amorphous silicon layer overlying the crystalline silicon wafer.

17. The solar cell of claim 16, wherein the p-type amorphous silicon layer is an emitter underlying the top cadmium oxide layer.

18. The solar cell of claim 15, further comprising an n-type amorphous silicon layer underlying the semiconductor wafer and overlying the bottom cadmium oxide layer.

19. The solar cell of claim 13, wherein the top cadmium oxide layer has a thickness of 70 to 130 nm, and the bottom cadmium oxide layer has a thickness of 50 to 200 nm.

20. The solar cell of claim 13, wherein the semiconductor wafer comprises a multi-junction solar cell structure, and the solar cell further comprises an emitter layer overlying the multi-junction solar cell structure and underlying the top cadmium oxide layer.

21. A method, comprising:
forming a solar cell structure;
forming a cadmium oxide layer underlying or overlying the solar cell structure; and
doping the cadmium oxide layer with an n-type dopant.

22. The method of claim 21, wherein the cadmium oxide layer is formed by sputtering.

23. The method of claim 21, wherein the cadmium oxide layer is formed to have a thickness of 50 to 300 nm.

24. The method of claim 21, wherein the cadmium oxide layer is doped with indium.

25. The method of claim 21, wherein the cadmium oxide layer is doped with gallium.

26. The method of claim 21, further comprising forming the cadmium oxide layer using an alloy of CdO with a metal-oxide to adjust a transmission spectrum of the cadmium oxide layer.

27. The method of claim 26, wherein the metal-oxide is ZnO or MgO.
